(19) United States
(12) Patent Application Publication
(10) Pub. No.: US 2026/0367177 A1
(43) Pub. Date: Nov. 19, 2026

(54) BATTERY DIAGNOSIS APPARATUS AND METHOD FOR DIAGNOSING ABNORMAL VOLTAGE VARIATION

(71) Applicants: Hyundai Motor Company, Seoul (KR); Kia Corporation, Seoul (KR)

(72) Inventor: Junghyun Lee, Hwaseong (KR)

(21) Appl. No.: 19/371,719

(22) Filed: Oct. 28, 2025

(30) Foreign Application Priority Data
May 16, 2025 (KR) 10-2025-0063898

(51) Int. Cl. G01R 31/396; G01R 31/36; G01R 31/374; G01R 31/388; G01R 31/392

(52) U.S. Cl. CPC G01R 31/396; G01R 31/3648; G01R 31/374; G01R 31/388; G01R 31/392

(57) ABSTRACT

The present disclosure relates to a battery diagnosis apparatus and a method for diagnosing abnormal voltage variation based on a variation in voltage deviation at a battery cell group level. A battery diagnosis apparatus according to an exemplary embodiment of the present disclosure may include a voltage deviation determining unit configured to determine a voltage deviation of a battery cell group formed by grouping a plurality of battery cells, and a battery diagnosis unit configured to diagnose abnormal voltage variation in the battery cell group based on a variation in voltage deviation of the battery cell group.

### CROSS-REFERENCE TO RELATED APPLICATION

This present application claims, under 35 U.S.C. § 119(a), the benefit of Korean Patent Application No. 10-2025-0063898, filed May 16, 2025, in the Korean Intellectual Property Office, the entire contents of which are incorporated herein by reference.

### BACKGROUND

### (a) Technical Field

The present disclosure relates to a battery diagnosis apparatus and a method for diagnosing abnormal voltage variation and, more particularly, to a battery diagnosis apparatus and a method for diagnosing abnormal voltage variation based on a variation in voltage deviation at a battery cell group level.

### (b) Background

Generally, a battery pack may comprise a plurality of battery cells connected in series and/or in parallel. A battery cell may comprise components such as a positive electrode current collector, a negative electrode current collector, a separator, an active material, and an electrolyte, and may be configured to perform repeated charging and discharging through electrochemical reactions among these components.

Such battery cells are designed to have high density and high energy and, therefore, ensuring safety is critical since abnormal behavior may lead to hazardous situations. In this regard, abnormal behavior of battery cells may manifest as a voltage drop caused by instantaneous short circuits or hardware failures in the battery cells. Therefore, to ensure stability of battery cells, a method for diagnosing abnormal voltage variations, such as a rapid voltage drop, is needed.

The matters described in this Background section are only for enhancement of understanding of the background of the disclosure, and should not be taken as acknowledgement that they correspond to prior art already known to those skilled in the art.

### SUMMARY

The following summary presents a simplified summary of certain features. The summary is not an extensive overview and is not intended to identify key or critical elements.

The present disclosure is directed to providing a battery diagnosis apparatus and a method for diagnosing abnormal voltage variation based on a variation in voltage deviation at a battery cell group level.

The present disclosure is directed to providing a battery diagnosis apparatus and a method for diagnosing abnormal voltage variation, which may improve diagnostic accuracy in diagnosing abnormal voltage variation based on a variation in voltage deviation at a battery cell group level.

The present disclosure is not limited to what has been described above, and other aspects not mentioned herein will be apparent from the following description to one of ordinary skill in the art to which the present disclosure pertains. Moreover, aspects of the present disclosure may be realized by the means and combinations thereof indicated in claims.

An aspect of the present disclosure may provide a battery diagnosis apparatus including a voltage deviation determining unit configured to determine a voltage deviation of a battery cell group formed by grouping a plurality of battery cells, and a battery diagnosis unit configured to diagnose abnormal voltage variation in the battery cell group based on a variation in voltage deviation of the battery cell group.

The battery diagnosis apparatus may further include a stabilization determining unit configured to determine whether the battery cell group is in a battery stabilization state that satisfies diagnostic allowable conditions during a charging or parked state of a vehicle.

The diagnostic allowable conditions may include a rate of current variation during charging or discharging being less than a target rate of current variation.

The voltage deviation determining unit may be configured to determine a voltage deviation of the battery cell group as a difference between a reference battery cell voltage and a smallest battery cell voltage in the battery cell group. The reference battery cell voltage may include one of a largest battery cell voltage, an average value of individual battery cell voltages, or a median value of the individual battery cell voltages in the battery cell group.

The voltage deviation determining unit may be configured to determine a voltage deviation of the battery cell group when a target wait time has elapsed from a time point at which the battery cell group is determined to be in the battery stabilization state.

The battery diagnosis unit may be configured to diagnose abnormal voltage variation in the battery cell group based on a variation in voltage deviation of the battery cell group corresponding to an abnormal variation in voltage deviation equal to or greater than a diagnostic threshold, the abnormal variation in voltage deviation increasing consecutively for a target number of times or more, and the consecutively increasing abnormal variation in voltage deviation being cumulatively detected at least the target number of times during one discharge cycle (1 DC).

The battery diagnosis unit may be configured to compare voltage deviations of the battery cell group at respective time points spaced by a target time interval with one another. When a variation in voltage deviation, which is defined as a difference between a voltage deviation at a current time point and a voltage deviation at an immediately preceding time point, is first detected to be equal to or greater than the diagnostic threshold, the battery diagnosis unit is configured to compare voltage deviations at respective time points following the current time point based on the voltage deviation at the immediately preceding time point.

Another aspect of the present disclosure may provide a method for diagnosing abnormal voltage variation performed by a battery diagnosis apparatus, the method including determining a voltage deviation of a battery cell group formed by grouping a plurality of battery cells, and diagnosing abnormal voltage variation in the battery cell group based on a variation in voltage deviation of the battery cell group.

The diagnosing the abnormal voltage variation may include determining whether the battery cell group is in a battery stabilization state that satisfies diagnostic allowable conditions during a charging or parked state of a vehicle.

The determining whether the battery cell group is in the battery stabilization state may include determining the battery cell group to be in the battery stabilization state when a rate of current variation during charging or discharging is less than a target rate of current variation, based on the diagnostic allowable conditions.

The determining the voltage deviation may include determining a voltage deviation of the battery cell group as a difference between a reference battery cell voltage and a smallest battery cell voltage in the battery cell group, and wherein the reference battery cell voltage may include one of a largest battery cell voltage, an average value of individual battery cell voltages, or a median value of the individual battery cell voltages in the battery cell group.

The diagnosing the abnormal voltage variation may include diagnosing abnormal voltage variation in the battery cell group based on a variation in voltage deviation of the battery cell group corresponding to an abnormal variation in voltage deviation equal to or greater than a diagnostic threshold, the abnormal variation in voltage deviation increasing consecutively for a target number of times or more, and the consecutively increasing abnormal variation in voltage deviation being cumulatively detected at least the target number of times during one discharge cycle (1 DC).

The diagnosing the abnormal voltage variation may include comparing voltage deviations of the battery cell group at respective time points spaced by a target time interval with one another, and when a variation in voltage deviation, which is defined as a difference between a voltage deviation at a current time point and a voltage deviation at an immediately preceding time point, is first detected to be equal to or greater than the diagnostic threshold, comparing voltage deviations at respective time points following the current time point based on the voltage deviation at the immediately preceding time point.

Still another aspect of the present disclosure may provide a battery diagnosis apparatus including a memory having instructions stored thereon, and a processor configured to, by executing the instructions, determine a voltage deviation of a battery cell group formed by grouping a plurality of battery cells and diagnose abnormal voltage variation in the battery cell group based on a variation in voltage deviation of the battery cell group.

The processor may be configured to determine a voltage deviation of the battery cell group as a difference between a reference battery cell voltage and a smallest battery cell voltage in the battery cell group. The reference battery cell voltage may include one of a largest battery cell voltage, an average value of individual battery cell voltages, or a median value of the individual battery cell voltages in the battery cell group.

The processor may be configured to diagnose abnormal voltage variation in the battery cell group based on a variation in voltage deviation of the battery cell group corresponding to an abnormal variation in voltage deviation equal to or greater than a diagnostic threshold, the abnormal variation in voltage deviation increasing consecutively for a target number of times or more, and the consecutively increasing abnormal variation in voltage deviation being cumulatively detected at least the target number of times during one discharge cycle (1 DC).

According to embodiments of the present disclosure, abnormal voltage variation in a battery cell group formed by grouping a plurality of battery cells (e.g., an entire module, a whole system, or a unit for repair or replacement) may be diagnosed by detecting a variation in voltage deviation equal to or greater than a diagnostic threshold.

In addition, according to embodiments of the present disclosure, by performing an abnormal voltage variation diagnosis in a battery stabilization state of a battery cell group, misdiagnosis may be prevented, and validity and accuracy of the diagnosis result may be improved by finalizing the diagnosis result only when a variation in voltage deviation equal to or greater than a diagnostic threshold is cumulatively detected during the abnormal voltage variation diagnosis.

According to an aspect of the present disclosure, a battery diagnosis apparatus is provided. The battery diagnosis apparatus may comprise a voltage deviation determining unit configured to determine a voltage deviation of a battery cell group including a plurality of battery cells. The battery diagnosis apparatus may comprise a processor and a memory, configured to diagnose abnormal voltage variation in the battery cell group based on a variation in voltage deviation of the battery cell group.

According to an exemplary embodiment, the battery diagnosis apparatus may comprise a stabilization determining unit configured to determine whether the battery cell group is in a battery stabilization state that satisfies one or more diagnostic allowable conditions during a charging or parked state of a vehicle.

According to an exemplary embodiment, the one or more diagnostic allowable conditions may comprise at least one of a state of charge (SOC) being equal to or greater than a target level; or a battery temperature being equal to or greater than a target temperature.

According to an exemplary embodiment, the one or more diagnostic allowable conditions may comprise at least one of a rate of current variation during charging or discharging being less than a target rate of current variation.

According to an exemplary embodiment, the one or more diagnostic allowable conditions may comprise a current time point being a time point at which a target wait time has elapsed after an ignition device was switched to an OFF state (IG OFF).

According to an exemplary embodiment, the one or more diagnostic allowable conditions may comprise no sensing error occurring in a voltage sensor during voltage sensing for the battery cell group.

According to an exemplary embodiment, the voltage deviation determining unit may be configured to determine a voltage deviation of the battery cell group as a difference between a reference battery cell voltage and a smallest battery cell voltage in the battery cell group, and the reference battery cell voltage comprises one of: a largest battery cell voltage in the battery cell group; an average value of individual battery cell voltages in the battery cell group; or a median value of the individual battery cell voltages in the battery cell group.

According to an exemplary embodiment, the voltage deviation determining unit may be configured to determine a voltage deviation of the battery cell group when a target wait time has elapsed from a time point at which the battery cell group is determined to be in a battery stabilization state.

According to an exemplary embodiment, the battery diagnosis apparatus may comprise a battery diagnosis unit, comprising the processor and the memory, configured to: diagnose abnormal voltage variation in the battery cell group based on a variation in voltage deviation of the battery cell group corresponding to an abnormal variation in voltage deviation equal to or greater than a diagnostic threshold, the abnormal variation in voltage deviation may increase consecutively for a target number of times or more, and the consecutively increasing abnormal variation in voltage deviation may be cumulatively detected at least the target number of times during one discharge cycle (1 DC).

According to an exemplary embodiment, the battery diagnosis apparatus may comprise a battery diagnosis unit, comprising the processor and the memory, configured to: compare voltage deviations of the battery cell group at respective time points spaced by a target time interval with one another, and, when a variation in voltage deviation, which is defined as a difference between a voltage deviation at a current time point and a voltage deviation at an immediately preceding time point, is first detected to be equal to or greater than the diagnostic threshold, compare voltage deviations at respective time points following the current time point based on the voltage deviation at the immediately preceding time point.

According to an exemplary embodiment, the battery diagnosis apparatus may comprise a battery diagnosis unit, comprising the processor and the memory, configured to: compare voltage deviations of the battery cell group at respective time points with one another when no voltage instability factor that causes the reference battery cell voltage to fluctuate is detected, and an increase in the magnitude of the reference battery cell voltage does not result in an increase in the voltage deviation.

According to an aspect of the present disclosure, a method for diagnosing abnormal voltage variation performed by a battery diagnosis apparatus is provided. The method may comprise, using a computing device comprising a processor and a memory, determining a voltage deviation of a battery cell group comprising a plurality of battery cells, and diagnosing abnormal voltage variation in the battery cell group based on a variation in voltage deviation of the battery cell group.

According to an exemplary embodiment, the diagnosing the abnormal voltage variation may comprise determining whether the battery cell group is in a battery stabilization state that satisfies one or more diagnostic allowable conditions during a charging or parked state of a vehicle.

According to an exemplary embodiment, the determining whether the battery cell group is in the battery stabilization state may comprise determining that the battery cell group is in the battery stabilization state when a rate of current variation during charging or discharging is less than a target rate of current variation, based on the diagnostic allowable conditions.

According to an exemplary embodiment, the determining the voltage deviation may comprise determining a voltage deviation of the battery cell group as a difference between a reference battery cell voltage and a smallest battery cell voltage in the battery cell group, and the reference battery cell voltage may comprise one of: a largest battery cell voltage in the battery cell group; an average value of individual battery cell voltages in the battery cell group; or a median value of the individual battery cell voltages in the battery cell group.

According to an exemplary embodiment, the diagnosing the abnormal voltage variation may comprise diagnosing abnormal voltage variation in the battery cell group based on a variation in voltage deviation of the battery cell group corresponding to an abnormal variation in voltage deviation equal to or greater than a diagnostic threshold, the abnormal variation in voltage deviation may increase consecutively for a target number of times or more, and the consecutively increasing abnormal variation in voltage deviation may be cumulatively detected at least the target number of times during one discharge cycle (1 DC).

According to an exemplary embodiment, the diagnosing the abnormal voltage variation may comprise comparing voltage deviations of the battery cell group at respective time points spaced by a target time interval with one another; and, when a variation in voltage deviation, which is defined as a difference between a voltage deviation at a current time point and a voltage deviation at an immediately preceding time point, is first detected to be equal to or greater than the diagnostic threshold, comparing voltage deviations at respective time points following the current time point based on the voltage deviation at the immediately preceding time point.

According to an aspect of the present disclosure, a battery diagnosis apparatus is provided. The battery diagnosis apparatus may comprise a computing device comprising a processor a memory. The memory may be configured to store instructions that, when executed by the processor, are configured to cause the processor to determine a voltage deviation of a battery cell group formed by grouping a plurality of battery cells, and diagnose abnormal voltage variation in the battery cell group based on a variation in voltage deviation of the battery cell group.

According to an exemplary embodiment, the computing device may be configured to determine a voltage deviation of the battery cell group as a difference between a reference battery cell voltage and a smallest battery cell voltage in the battery cell group, and the reference battery cell voltage may comprise one of: a largest battery cell voltage in the battery cell group; an average value of individual battery cell voltages in the battery cell group; or a median value of the individual battery cell voltages in the battery cell group.

According to an exemplary embodiment, the computing device may be configured to diagnose abnormal voltage variation in the battery cell group based on a variation in voltage deviation of the battery cell group corresponding to an abnormal variation in voltage deviation equal to or greater than a diagnostic threshold, the abnormal variation in voltage deviation may increase consecutively for a target number of times or more, and the consecutively increasing abnormal variation in voltage deviation may be cumulatively detected at least the target number of times during one discharge cycle (1 DC).

### BRIEF DESCRIPTION OF THE DRAWINGS

The foregoing and other aspects, features, and advantages, as well as the following detailed description of the embodiments, will be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 is a diagram illustrating a structure of a battery diagnosis environment, according to an exemplary embodiment of the present disclosure.

FIG. 2 is a block diagram illustrating a configuration of a battery diagnosis apparatus, according to an exemplary embodiment of the present disclosure.

FIG. 3 is a diagram exemplarily illustrating voltage variation values for a plurality of battery cells, according to an exemplary embodiment of the present disclosure.

FIGS. 4 and 5 are flowcharts illustrating a method for diagnosing abnormal voltage variation, according to an exemplary embodiment of the present disclosure.

FIG. 6 illustrates example elements of a computing device, according to an exemplary embodiment of the present disclosure.

### DETAILED DESCRIPTION

Hereinafter, exemplary embodiments disclosed in the present document will be described in detail with reference to the accompanying drawings. Like reference numerals designate like elements, and redundant descriptions thereof will be omitted. Further, such as “module” and a “unit”, suffixes for components used in the following description are given or mixed and used by considering easiness in preparing a specification and do not have a meaning or role distinguished from each other in themselves. In addition, in describing an embodiment disclosed in the present document, if it is determined that a detailed description of a related art incorporated herein unnecessarily obscure the gist of the embodiment, the detailed description thereof will be omitted. Furthermore, it should be understood that the appended drawings are intended only to help understand embodiments disclosed in the present document and do not limit the technical principles and scope of the present disclosure; rather, it should be understood that the appended drawings include all of the modifications, equivalents or substitutes described by the technical principles and belonging to the technical scope of the present disclosure.

Although the terms first, second, and the like, may be used herein to describe various elements, these elements should not be limited by these terms. These terms are generally only used to distinguish one element from another.

When an element or layer is referred to as being “on,” “engaged to,” “connected to,” or “coupled to” another element or layer, it may be directly on, engaged, connected, or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present.

When a component, unit, device, element, apparatus, or the like of the present disclosure is described as having a purpose or performing an operation, function, or the like, the component, unit, device, element, apparatus, or the like should be considered herein as being “configured to” meet that purpose or to perform that operation or function. Each component, unit, device, element, apparatus, and the like may separately embody or be included with a processor and a memory, such as a non-transitory computer readable media, as part of the apparatus.

The term “unit” or “module” used in this specification signifies one unit that processes at least one function or operation, and may be realized by hardware, software, or a combination thereof. The operations of the method or the functions described in connection with the forms disclosed herein may be embodied directly in a hardware or a software module executed by a processor, or in a combination thereof.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, and C”, “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

Various techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, perform one or more of the methods described herein. The non-transitory processor-readable data storage medium may form part of a computer program product, which may include packaging materials.

The non-transitory processor-readable storage medium may comprise random access memory (RAM) such as synchronous dynamic random access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor.

Various embodiments described herein may be executed by one or more processors, such as one or more motion processing units (MPUs), sensor processing units (SPUs), host processor(s) or core(s) thereof, digital signal processors (DSPs), general purpose microprocessors, application specific integrated circuits (ASICs), application specific instruction set processors (ASIPs), field programmable gate arrays (FPGAs), a programmable logic controller (PLC), a complex programmable logic device (CPLD), a discrete gate or transistor logic, discrete hardware components, or any combination thereof designed to perform the functions described herein, or other equivalent integrated or discrete logic circuitry. The term “processor,” as used herein may refer to any of the foregoing structures or any other structure suitable for implementation of the techniques described herein. As employed in the subject specification, the term “processor” can refer to substantially any computing processing unit or device comprising, but not limited to comprising, single-core processors; single-processors with software multithread execution capability; multi-core processors; multi-core processors with software multithread execution capability; multi-core processors with hardware multithread technology; parallel platforms; and parallel platforms with distributed shared memory. Moreover, processors can exploit nano-scale architectures such as, but not limited to, molecular and quantum-dot based transistors, switches and gates, in order to optimize space usage or enhance performance of user equipment. A processor may also be implemented as a combination of computing processing units.

In addition, in some aspects, the functionality described herein may be provided within dedicated software modules or hardware modules configured as described herein. Also, the techniques could be fully implemented in one or more circuits or logic elements. A general purpose processor may be a microprocessor, but in the alternative, the processor may be any processor, controller, microcontroller, or state machine. A processor may also be implemented as a combination of computing devices, e.g., a combination of an SPU/MPU and a microprocessor, a plurality of microprocessors, one or more microprocessors in conjunction with an SPU core, MPU core, or any other such configuration. One or more components of an SPU or electronic device described herein may be embodied in the form of one or more of a “chip,” a “package,” an Integrated Circuit (IC).

It is understood that the terms “vehicle”, “vehicular”, and other similar terms as used herein are inclusive of motor vehicles in general, such as passenger automobiles including sport utility vehicles (SUVs), buses, trucks, various commercial vehicles, watercraft including a variety of boats and ships, aircraft, and the like, and include hybrid vehicles, electric vehicles, plug-in hybrid electric vehicles, hydrogen-powered vehicles, and other alternative fuel vehicles (e.g., fuels derived from resources other than petroleum). As referred to herein, a hybrid vehicle is a vehicle that has two or more sources of power, for example, vehicles powered by both gasoline and electricity.

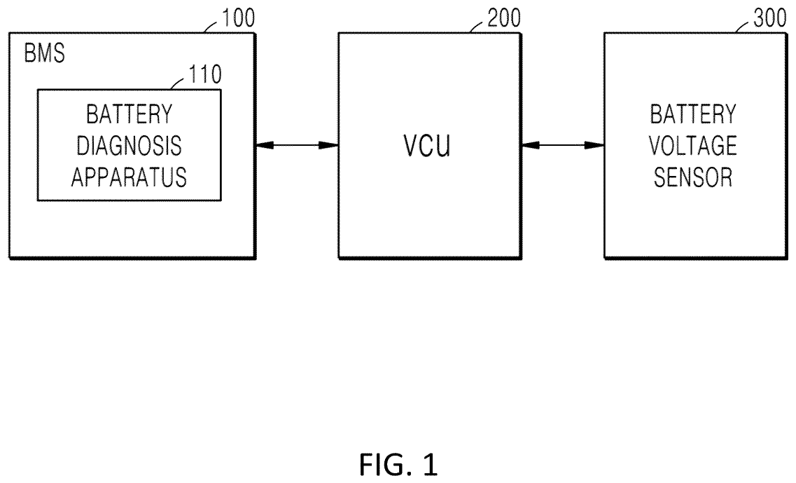

Hereinafter, a battery diagnosis apparatus and a method for diagnosing abnormal voltage variation according to embodiments of the present disclosure will be described in detail with reference to FIGS. 1 to 6.

Typically, abnormal behavior of a battery cell may manifest as a voltage drop caused by instantaneous short circuits or hardware failures in the battery cells, and such a voltage drop may significantly reduce stability of the battery cell. Therefore, to ensure the stability of the battery cell, a method for diagnosing abnormal voltage variation, such as a rapid voltage drop, may need to be established.

Accordingly, in an exemplary embodiment of the present disclosure, a method is provided for diagnosing abnormal voltage variation based on a variation in voltage deviation of a battery cell group.

FIG. 1 is a diagram illustratively showing a structure of a battery diagnosis environment, according to an exemplary embodiment of the present disclosure.

Referring to FIG. 1, a battery diagnosis environment, according to an exemplary embodiment of the present disclosure, may comprise a battery management system (BMS) 100 configured to monitor voltage deviations of a plurality of battery cells via a vehicle control unit (VCU) 200 and a battery voltage sensor 300.

The BMS 100 may comprise a battery diagnosis apparatus 110. The battery diagnosis apparatus 110 may be configured to group a plurality of battery cells into a battery cell group (e.g., an entire module, a whole system, or a unit for repair or replacement), and diagnose abnormal voltage variation in the battery cell group based on a variation in voltage deviation of the battery cell group.

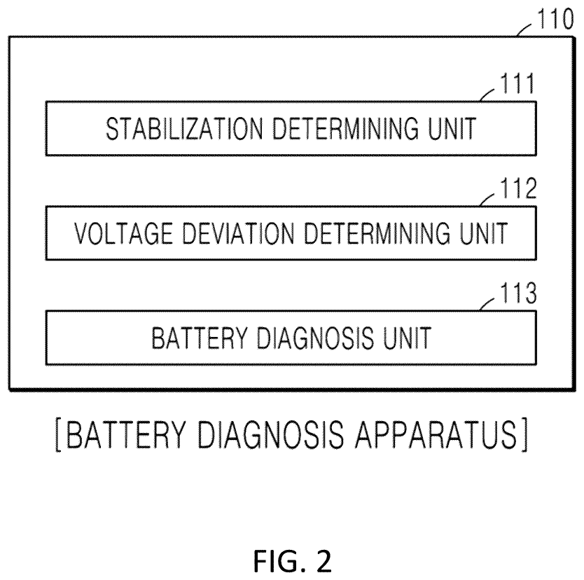

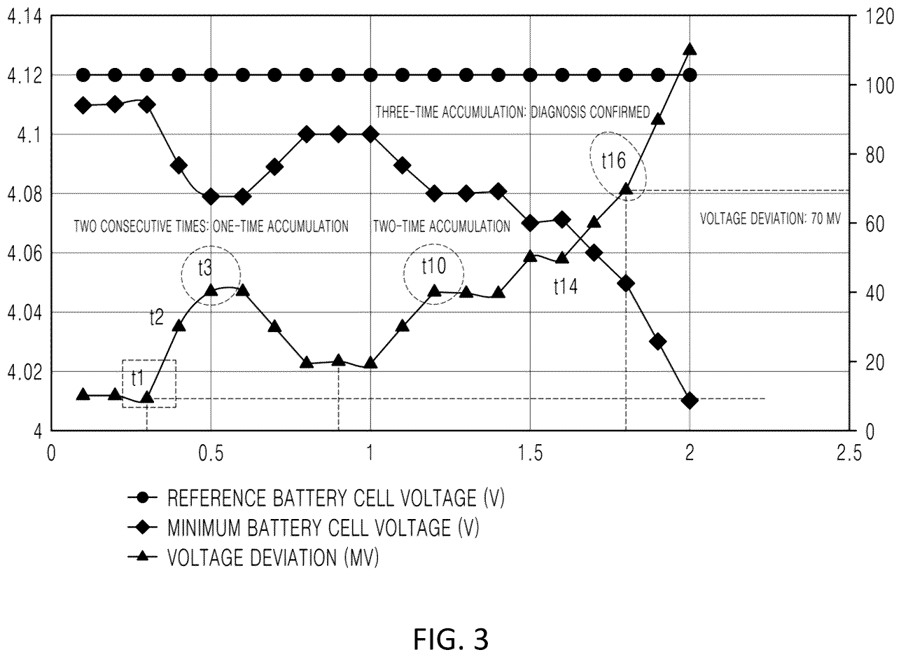

The following describes a battery diagnosis apparatus, according to an exemplary embodiment of the present disclosure, with reference to FIGS. 2 to 3.

FIG. 2 is a block diagram illustrating a configuration of a battery diagnosis apparatus 110, according to an exemplary embodiment of the present disclosure. According to an exemplary embodiment, the battery diagnosis apparatus 110 may comprise a computing device.

Referring to FIG. 2, a battery diagnosis apparatus 110 according to an exemplary embodiment of the present disclosure, may comprise a memory configured to store instructions thereon and a processor configured to execute the instructions stored in the memory.

The processor, according to an exemplary embodiment of the present disclosure, may comprise a functional configuration including a stabilization determining unit 111, a voltage deviation determining unit 112, and a battery diagnosis unit 113, according to functionalities implemented by executing the instructions.

As described above, the battery diagnosis apparatus 110, according to an exemplary embodiment of the present disclosure, may be configured to diagnose abnormal voltage variation in a battery cell group through the functional configuration of the processor described above. Hereinafter, a more detailed description will be given of each functional configuration for implementing the functionality of diagnosing abnormal voltage variation in the battery cell group.

The stabilization determining unit 111 may be configured to determine whether the battery cell group is in a battery stabilization state. Such determination may serve to prevent misdiagnosis for the battery cell group during the performance of an actual abnormal voltage variation diagnosis.

In this regard, the stabilization determining unit 111 may be configured to determine whether the battery cell group is in a battery stabilization state that satisfies diagnostic allowable conditions during a charging state (loaded state) or a parked state (no-load state) of a vehicle.

The diagnostic allowable conditions, according to an exemplary embodiment of the present disclosure, may comprise detailed conditions set with a target level of state of charge (SOC) (e.g., 20%) and a target temperature (e.g., 0 °C).

Such conditions may be provided to prevent misdiagnosis that may occur due to increased voltage deviations between battery cells under low SOC or low temperature conditions.

The stabilization determining unit 111 may be configured to determine the battery cell group to be in the battery stabilization state according to the above detailed conditions when the SOC is equal to or greater than a target level (e.g., 20%) and the battery temperature is equal to or greater than a target temperature (e.g., 0 °C).

The diagnostic allowable conditions, according to an exemplary embodiment of the present disclosure, may further comprise, as a detailed condition, a target rate of current variation during charging or discharging (e.g., 1 A).

The stabilization determining unit 111 may be configured to determine the battery cell group to be in the battery stabilization state according to the above detailed conditions when a rate of current variation during charging or discharging is less than the target rate of current variation (e.g., 1 A).

The diagnostic allowable conditions, according to an exemplary embodiment of the present disclosure, may further comprise, as a detailed condition, a target wait time (e.g., 5 seconds) measured from when an ignition device is switched to an OFF state (IG OFF).

The stabilization determining unit 111 may be configured to determine the battery cell group to be in the battery stabilization state according to the above detailed conditions when a current time point corresponds to a time point at which the target wait time (e.g., 5 seconds) has elapsed after the ignition device was switched to the OFF state (IG OFF).

The diagnostic allowable conditions, according to an exemplary embodiment of the present disclosure, may further comprise, as a detailed condition, whether a sensing error occurs in a voltage sensor.

The stabilization determining unit 111 may be configured to determine the battery cell group to be in the battery stabilization state according to the above detailed conditions when no sensing error occurs in the voltage sensor during voltage sensing for the battery cell group.

As such, it may be seen that, in an exemplary embodiment of the present disclosure, various detailed conditions may be defined and applied as the diagnostic allowable conditions to determine the battery stabilization state of the battery cell group.

Each detailed condition included in the diagnostic allowable conditions may be selectively applied and arranged in any determination order according to operator settings.

The voltage deviation determining unit 112 may be configured to start counting time when the state of the battery cell group is determined to be in the battery stabilization state satisfying the diagnostic allowable conditions, and determine whether a target wait time (e.g., 30 seconds) has elapsed from that time point.

This target wait time determination may serve to ensure sufficient stabilization of the voltage state of the battery cell group, thereby preventing errors in the subsequent voltage deviation determination process.

The voltage deviation determining unit 112 may be configured to determine a voltage deviation of the battery cell group when a target wait time has elapsed after the battery cell group was determined to be in the battery stabilization state.

For example, the voltage deviation determining unit 112 may be configured to determine a voltage deviation (Vdiff) of the battery cell group at respective time points spaced by a target time interval (e.g., 100 ms), as a difference between a reference battery cell voltage (Vref) of the battery cell group and a smallest battery cell voltage (Vmin) in the battery cell group, as indicated in Equation 1.

V_{diff}=V_{ref}−Vₘᵢₙ Equation 1

V_{diff} is the voltage deviation, V_{ref} is the reference battery cell voltage, and Vₘᵢₙ is the minimum battery cell voltage.

Here, the reference battery cell voltage (V_{ref}) may be defined as one of a largest battery cell voltage, an average value of individual battery cell voltages, or a median value of the individual battery cell voltages in the battery cell group.

The voltage deviation determining unit 112 may be configured to determine a voltage deviation of the battery cell group as a difference between the defined reference battery cell voltage (V_{ref}) and the minimum battery cell voltage (Vₘᵢₙ) in the battery cell group.

According to an exemplary embodiment of the present disclosure, when either the average value or the median value of individual battery cell voltages in the battery cell group is defined as the reference battery cell voltage (V_{ref}), the smallest battery cell voltage in the battery cell group may be excluded from the population, thereby improving diagnostic sensitivity.

When voltage deviations of the battery cell group are determined, the battery diagnosis unit 113 may be configured to determine whether a variation in voltage deviation can be determined for diagnosing abnormal voltage variation.

For example, the battery diagnosis unit 113 may be configured to determine that a variation in voltage deviation can be determined when no voltage instability factor (e.g., user ignition, 12V auxiliary charging, or other battery load events) that may cause the reference battery cell voltage ( V_{ref}) to fluctuate is detected, and an increase in the magnitude of the reference battery cell voltage ( V_{ref}) does not result in an increase in the voltage deviation.

According to an exemplary embodiment of the present disclosure, determining whether a variation in voltage deviation may be determined may serve to verify whether the voltage state of the battery cell group is sufficiently stabilized, which may help prevent errors in the process of determining the variation in voltage deviation.

When it is determined that the variation in voltage deviation can be determined, the battery diagnosis unit 113 may be configured to determine variation in voltage deviations by comparing voltage deviations of the battery cell group at respective time points spaced by a target time interval (e.g., 100 ms), as indicated in Equation 2.

Voltage deviation variation=V_{diff(current point time)}−V_{diff(immediately preceding time point)} Equation 2

When a variation in voltage deviation, which is defined as a difference between a voltage deviation at the current time point and a voltage deviation at an immediately preceding time point, is first detected to be equal to or greater than the diagnostic threshold, the battery diagnosis unit 113 may be configured to determine variation in voltage deviations by comparing voltage deviations at respective time points following the current time point and the voltage deviation at the immediately preceding time point, which may be defined as a reference time point, as indicated in Equation 3.

Voltage deviation variation=V_{diff(current point time)}−V_{diff(reference time point)} Equation 3

In this regard, FIG. 3 illustratively shows variation in voltage deviations of a battery cell group, according to an exemplary embodiment of the present disclosure.

Referring to FIG. 3, when a variation in voltage deviation, which is defined as a difference between a voltage deviation at time point t1 and a voltage deviation at time point t2, is first detected to be equal to or greater than the diagnostic threshold, the voltage deviation at time point t1 may be defined as a voltage deviation at a reference time point. Accordingly, variation in voltage deviations may be determined by comparing the voltage deviations at respective time points following time point t2 (t3, t4, . . . , tn) and the voltage deviation at time point t1.

The reason for comparing voltage deviations at respective time points following the current time point with the voltage deviation at the reference time point is that such comparison may allow a variation in voltage deviation to reach a diagnostic threshold more quickly, thereby preventing delay in confirming a diagnosis that may occur when comparing voltage deviations between consecutive time points.

For example, the battery diagnosis unit 113 may be configured to diagnose abnormal voltage variation in the battery cell group based on a variation in voltage deviation of the battery cell group.

The battery diagnosis unit 113 may be configured to determine whether a variation in voltage deviation of the battery cell group is an abnormal variation in voltage deviation equal to or greater than a diagnostic threshold, and whether the abnormal variation in voltage deviation has increased continuously for a target number of times (e.g., two times) or more.

In general, abnormal behavior may exhibit voltage deviation characteristics such as a temporary increase followed by a return to the original state (wedge-shaped), an increase followed by a period of stabilization and subsequent further increase (stepwise increase), or a continuous increase with a linear or nonlinear rate of change.

Accordingly, in an exemplary embodiment of the present disclosure, by determining whether abnormal variation in voltage deviations equal to or greater than the diagnostic threshold consecutively increase for at least a target number of times, diagnosis may be performed in a manner that takes into account the above characteristics potentially exhibited by abnormal voltage deviation behavior.

Referring again to FIG. 3, when a variation in voltage deviation, which is defined as a difference between the voltage deviation at time point t1 and the voltage deviation at time point t2, is first detected to be equal to or greater than a diagnostic threshold, variation in voltage deviations at respective time points (t3, t4, . . . , tn) following time point t2 may be determined by comparing the voltage deviations at the respective time points and the voltage deviation at time point t1. Time points t3, t10, and t16 may then be identified as respective time points at which the variation in voltage deviations that are equal to or greater than the diagnostic threshold consecutively increase for at least a target number of times (e.g., two times).

The battery diagnosis unit 113 may be configured to count, as one event, the occurrence of abnormal variation in voltage deviations that are determined to have consecutively increased for at least a target number of times (e.g., two times). The battery diagnosis unit 113 may confirm an abnormal voltage variation diagnosis for the battery cell group when the number of such events accumulates to at least a target number (e.g., three times) within one discharge cycle (1 DC), which refers to a period from BMS power-on to power-off.

Referring again to FIG. 3, time points t3, t10, and t16 may be identified as time points at which the abnormal variation in voltage deviation has consecutively increased for at least a target number of times (e.g., two times). Accordingly, at time point t16, the abnormal voltage variation diagnosis for the battery cell group may be confirmed.

When the abnormal voltage variation diagnosis for the battery cell group is confirmed, a battery cell having a lowest voltage in the battery cell group may be determined as an abnormal cell.

According to an exemplary embodiment of the present disclosure, the abnormal voltage variation diagnosis for the battery cell group may be confirmed only when abnormal variation in voltage deviations equal to or greater than the diagnostic threshold are cumulatively detected. This may allow filtering out voltage sensor noise from the diagnosis result, thereby improving validity and accuracy of the diagnosis.

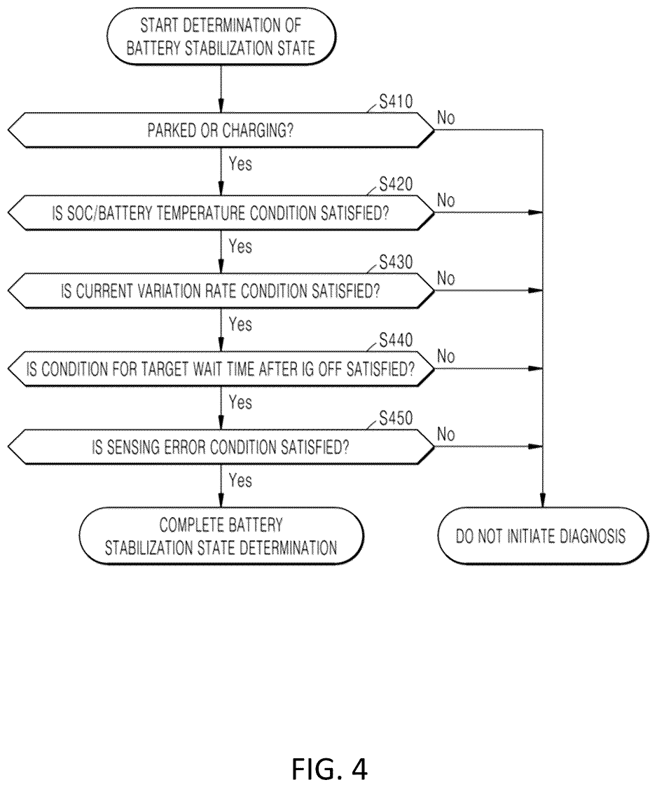

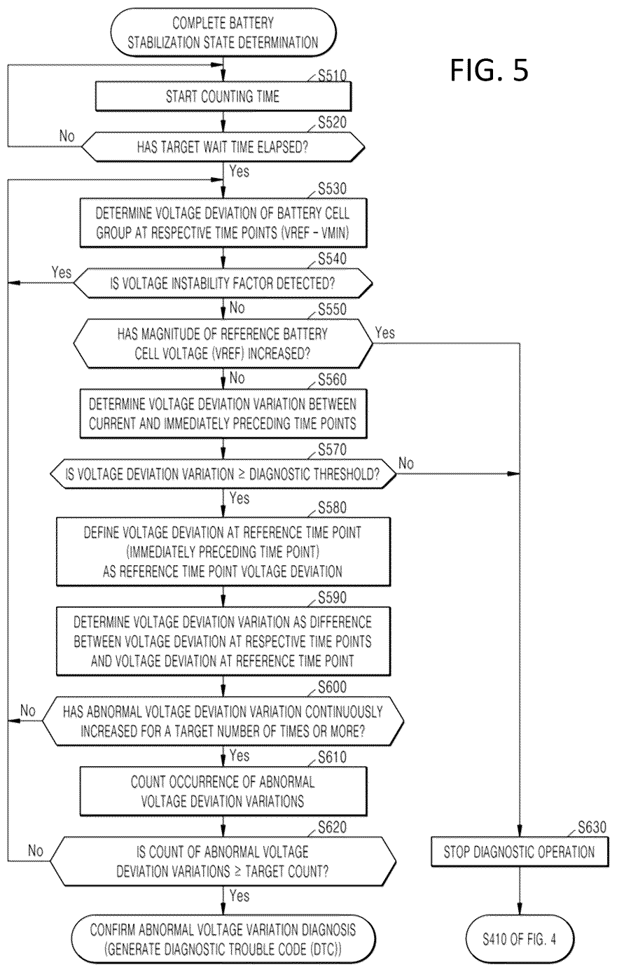

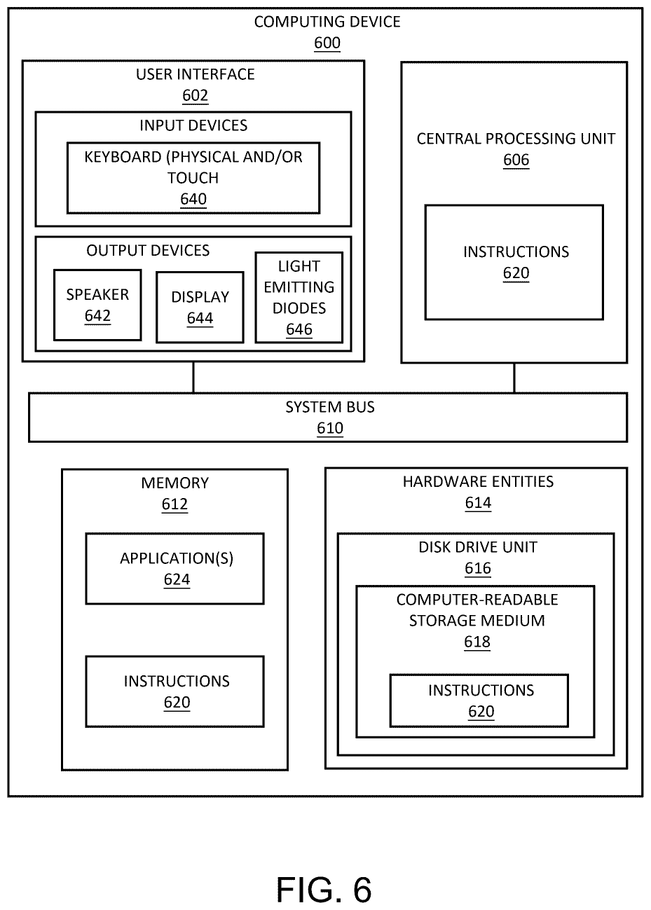

Hereinafter, a method for diagnosing abnormal voltage variation, according to an exemplary embodiment of the present disclosure, will be described with reference to FIGS. 4 and 5. The method may be performed by the battery diagnosis apparatus 110 described above with reference to FIG. 2 and/or the computing device 600 described below with reference to FIG. 6.

FIGS. 4 and 5 are flowcharts illustrating a method for diagnosing abnormal voltage variation, according to an exemplary embodiment of the present disclosure.

Referring first to FIG. 4, the battery diagnosis apparatus 110 may be configured in S410 to determine whether the battery cell group is in a battery stabilization state that satisfies diagnostic allowable conditions during a charging state (loaded state) or a parked state (no-load state) of a vehicle.

Such determination may serve to prevent misdiagnosis for the battery cell group during the performance of an actual abnormal voltage variation diagnosis.

If the result of S410 is “YES”, the battery diagnosis apparatus 110 may be configured in S420 to determine whether a state of charge (SOC) is equal to or greater than a target level (e.g., 20%) and a battery temperature is equal to or greater than a target temperature (e.g., 0 °C), based on diagnostic allowable conditions.

If the result of S420 is “YES”, the battery diagnosis apparatus 110 may be configured in S430 to determine whether a current variation rate during charging or discharging is less than a target current variation rate (e.g., 1 A) based on the diagnostic allowable conditions.

If the result of S430 is “YES”, the battery diagnosis apparatus 110 may be configured in S440 to determine whether the current time point corresponds to a time point at which a target wait time (e.g., 5 seconds) has elapsed after an ignition device was switched to an OFF state (IG OFF), based on the diagnostic allowable conditions.

If the result of S440 is “YES”, the battery diagnosis apparatus 110 may be configured in S450 to determine, based on the diagnostic allowable conditions, whether a sensing error of a voltage sensor occurs during voltage sensing for the battery cell group.

When no sensing error of the voltage sensor occurs, the battery diagnosis apparatus 110 may be configured to determine that the battery cell group is in a battery stabilization state that satisfies all diagnostic allowable conditions.

On the other hand, when any of the diagnostic allowable conditions is not satisfied based on the determinations in steps S410 to S450, the battery diagnosis apparatus 110 may not perform the abnormal voltage variation diagnosis on the battery cell group.

Referring to FIG. 5, when the battery cell group is determined to be in a battery stabilization state that satisfies the diagnostic allowable conditions, the battery diagnosis apparatus 110 may be configured to start counting time in S510 and to determine in S520 whether a target wait time (e.g., 30 seconds) has elapsed after the time point at which the battery cell group was determined to be in the battery stabilization state.

This target wait time determination may serve to ensure sufficient stabilization of the voltage state of the battery cell group, thereby preventing errors in the subsequent voltage deviation determination process.

If the result of S520 is “YES”, the battery diagnosis apparatus 110 may be configured in S530 to determine a voltage deviation of the battery cell group.

For example, the battery diagnosis apparatus 110 may be configured to determine a voltage deviation (V_{diff}) of the battery cell group at respective time points spaced by a target time interval (e.g., 100 ms), as a difference between a reference battery cell voltage (V_{ref}) of the battery cell group and a smallest battery cell voltage (Vₘᵢₙ) in the battery cell group.

Here, the reference battery cell voltage (V_{ref}) may be defined as one of a largest battery cell voltage, an average value of individual battery cell voltages, or a median value of the individual battery cell voltages in the battery cell group.

The battery diagnosis apparatus 110 may be configured to determine the voltage deviation of the battery cell group as a difference between the defined reference battery cell voltage (V_{ref}) and the minimum battery cell voltage (Vₘᵢₙ) in the battery cell group.

According to an exemplary embodiment of the present disclosure, when either an average value or a median value of individual battery cell voltages in the battery cell group is defined as the reference battery cell voltage (V_{ref}), the smallest battery cell voltage in the battery cell group may be excluded from the population, thereby improving diagnostic sensitivity.

When the voltage deviation of the battery cell group is determined, the battery diagnosis apparatus 110 may be configured in S540 and S550 to determine whether a variation in voltage deviation can be determined for diagnosing abnormal voltage variation.

For example, the battery diagnosis apparatus 110 may be configured to determine that the variation in voltage deviation can be determined when no voltage instability factor (e.g., user ignition, 12V auxiliary charging, or other battery load events) that may cause the reference battery cell voltage (V_{ref}) to fluctuate is detected, and an increase (V_{ref}) in the magnitude of the reference battery cell voltage does not result in an increase in the voltage deviation.

According to an exemplary embodiment of the present disclosure, determining whether a variation in voltage deviation can be determined may serve to verify whether the voltage state of the battery cell group is sufficiently stabilized, which may help prevent errors in the process of determining the variation in voltage deviation.

When the voltage instability factor is determined to have occurred in S540, the battery diagnosis apparatus 110 may be configured to return to S530 to redetermine a voltage deviation of the battery cell group. When it is determined in S550 that the magnitude of the reference battery cell voltage (V_{ref}) has increased, the battery diagnosis apparatus 110 may stop the determination operation for diagnosis and proceed to S410 of FIG. 4.

When it is determined that the variation in voltage deviation can be determined, the battery diagnosis apparatus 110 may be configured in S560 to determine the variation in voltage deviation as a difference between the voltage deviation at the current time point and the voltage deviation at the immediately preceding time point according to the equation: V_{diff} (current time)−V_{diff} (immediately preceding time), the two time points being spaced apart by a target time interval (e.g., 100 ms). The apparatus may be configured in S570 to determine whether the determined variation in voltage deviation is equal to or greater than a diagnostic threshold.

When it is determined in S570 that the determined variation in voltage deviation is less than the diagnostic threshold, the process proceeds to S630, in which the battery diagnosis apparatus 110 may be configured to stop diagnostic operation and proceed to S410 of FIG. 4.

When the determined variation in voltage deviation is first detected to be equal to or greater than a diagnostic threshold, the battery diagnosis apparatus 110 may be configured in S580 to define the voltage deviation at the immediately preceding time point as a reference time point voltage deviation. In S590, the battery diagnosis apparatus 110 may be configured to determine a variation in voltage deviation as a difference between the voltage deviation at respective time points following the current time point and the voltage deviation at the reference time point using the equation: V_{diff} (respective time points following the current time point)−V_{diff} (reference time point).

Referring to FIG. 3, when a variation in voltage deviation, which is defined as a difference between the voltage deviation at time point t1 and the voltage deviation at time point t2, is first detected to be equal to or greater than a diagnostic threshold, the voltage deviation at time point t1 may be defined as the voltage deviation at the reference time point. Accordingly, variation in voltage deviations may be determined by comparing the voltage deviations at respective time points following t2 (t3, t4, . . . , tn) and the voltage deviation at time point t1.

The reason for comparing voltage deviations at respective time points following the current time point with the voltage deviation at the reference time point is that such comparison may allow a variation in voltage deviation to reach a diagnostic threshold more quickly, thereby preventing delay in confirming a diagnosis that may occur when comparing voltage deviations between consecutive time points.

In S600, the battery diagnosis apparatus 110 may be configured to determine whether a variation in voltage deviation of the battery cell group corresponds to an abnormal variation in voltage deviation equal to or greater than a diagnostic threshold, and whether the abnormal variation in voltage deviation has increased continuously for a target number of times (e.g., two times) or more.

In general, abnormal behavior may exhibit voltage deviation characteristics such as a temporary increase followed by a return to the original state (wedge-shaped), an increase followed by a period of stabilization and subsequent further increase (stepwise increase), or a continuous increase with a linear or nonlinear rate of change.

Accordingly, in an exemplary embodiment of the present disclosure, by determining whether abnormal variation in voltage deviations equal to or greater than the diagnostic threshold consecutively increase for at least a target number of times, diagnosis may be performed in a manner that takes into account the above characteristics potentially exhibited by abnormal voltage deviation behavior.

Referring again to FIG. 3, when a variation in voltage deviation, which is defined as a difference between the voltage deviation at time point t1 and the voltage deviation at time point t2, is first detected to be equal to or greater than a diagnostic threshold, variation in voltage deviations at respective time points (t3, t4, . . . , tn) following time point t2 may be determined by comparing the voltage deviations at the respective time points and the voltage deviation at time point t1. Time points t3, t10, and t16 may then be identified as respective time points at which the variation in voltage deviations that are equal to or greater than the diagnostic threshold consecutively increase for at least a target number of times (e.g., two times).

In S600, when it is determined that the abnormal variation in voltage deviations equal to or greater than the diagnostic threshold have not consecutively increased for at least the target number of times, the battery diagnosis apparatus 110 may return to S530. The apparatus may be configured in S530 to redetermine the voltage deviation of the battery cell group.

When the abnormal variation in voltage deviations of the battery cell group are determined to have consecutively increased for at least a target number of times (e.g., two times), the battery diagnosis apparatus 110 may be configured in S610 to count, as one event, the occurrence of abnormal variation in voltage deviations. In S620, when the number of counted events accumulates to at least a target number (e.g., three times) within one discharge cycle (1 DC), which refers to a period from BMS power-on to power-off, the battery diagnosis apparatus 110 may be configured to confirm an abnormal voltage variation diagnosis for the battery cell group and generate a diagnostic trouble code (DTC).

Referring again to FIG. 3, time points t3, t10, and t16 may be identified as time points at which the abnormal variation in voltage deviation has consecutively increased for at least a target number of times (e.g., two times). Accordingly, at time point t16, an abnormal voltage variation diagnosis for the battery cell group may be confirmed.

When the abnormal voltage variation diagnosis for the battery cell group is confirmed, a battery cell having a lowest voltage in the battery cell group may be determined as an abnormal cell.

When it is determined in S620 that the number of counted events does not accumulate to at least a target number (e.g., three times), the battery diagnosis apparatus 110 may be configured to proceed to S530 to redetermine the voltage deviation of the battery cell group.

According to an exemplary embodiment of the present disclosure, the abnormal voltage variation diagnosis for the battery cell group may be confirmed only when abnormal variation in voltage deviations equal to or greater than the diagnostic threshold are cumulatively detected. This may allow filtering out voltage sensor noise from the diagnosis result, thereby improving validity and accuracy of the diagnosis.

Referring now to FIG. 6, an illustration of an example architecture for a computing device 600 is provided. According to an exemplary embodiment, one or more functions of the present disclosure may be implemented by a computing device such as, e.g., computing device 600 or a computing device similar to computing device 600. Computing device 600 may be a quantum computer, a classical computer, and/or have one or more components configured to perform one or more quantum and/or classical computing functions. Battery diagnosis apparatus 110 may be an example of computing device 600 and/or may comprise one or more components of computing device 600.

The hardware architecture of FIG. 6 represents one example implementation of a representative computing device configured to implement at least a portion of the systems/devices and method(s)/control logic(s) described herein.

Some or all components of the computing device 600 may be implemented as hardware, software, and/or a combination of hardware and software. The hardware may comprise, but is not limited to, one or more electronic circuits. The electronic circuits may comprise, but are not limited to, passive components (e.g., resistors and capacitors) and/or active components (e.g., amplifiers and/or microprocessors). The passive and/or active components may be adapted to, arranged to, and/or programmed to perform one or more of the methodologies, procedures, or functions described herein.

As shown in FIG. 6, the computing device 600 may comprise a user interface 602 (e.g., a graphical user interface), a Central Processing Unit (“CPU”) 606, a system bus 610, a memory 612 connected to and accessible by other portions of computing device 600 through system bus 610, and hardware entities 614 connected to system bus 610. The user interface may comprise input devices and output devices, which may be configured to facilitate user-software interactions for controlling operations of the computing device 600. The input devices may comprise, but are not limited to, a physical and/or touch keyboard 640. The input devices may be connected to the computing device 600 via a wired or wireless connection (e.g., a Bluetooth® connection). The output devices may comprise, but are not limited to, a speaker 642, a display 644, and/or light emitting diodes 646.

At least some of the hardware entities 614 may be configured to perform actions involving access to and use of memory 612, which may be a Random Access Memory (RAM), a disk driver and/or a Compact Disc Read Only Memory (CD-ROM), among other suitable memory types. Hardware entities 614 may comprise a disk drive unit 616 comprising a computer-readable storage medium 618 on which may be stored one or more sets of instructions 620 (e.g., programming instructions such as, but not limited to, software code) configured to implement one or more of the methodologies, procedures, or functions described herein. The instructions 620 may also reside, completely or at least partially, within the memory 612 and/or within the CPU 606 during execution thereof by the computing device 600.

The memory 612 and the CPU 606 may also constitute machine-readable media. The term “machine-readable media”, as used here, refers to a single medium or multiple media (e.g., a centralized or distributed database, and/or associated caches and servers) that store the one or more sets of instructions 620. The term “machine-readable media”, as used here, also refers to any medium that is capable of storing, encoding, or carrying a set of instructions 620 for execution by the computing device 600 and that cause the computing device 600 to perform any one or more of the methodologies of the present disclosure. According to various embodiments, one or more computer applications 624 may be stored on the memory 612.

As used in the present disclosure (especially in the appended claims), the terms “a/an” and “the” include both singular and plural references, unless the context clearly states otherwise. Also, it should be understood that any numerical range recited in the present disclosure is intended to include all sub-ranges subsumed therein (unless expressly indicated otherwise) and accordingly, the disclosed numeral ranges include every individual value between the minimum and maximum values of the numeral ranges.

The steps constituting the method according to the present disclosure may be performed in an appropriate order unless a specific order is described or otherwise specified. That is, the present disclosure is not necessarily limited to the order in which the steps are recited. All examples described in the present disclosure or the terms indicative thereof (“for example”, “such as”) are merely to describe the present disclosure in greater detail. Therefore, it should be understood that the scope of the present disclosure is not limited to the example embodiments described above or by the use of such terms unless limited by the appended claims. Also, it should be apparent to those skilled in the art that various modifications, combinations, and alternations may be made depending on design conditions and factors within the scope of the appended claims or equivalents thereof.

The present disclosure is thus not limited to the example embodiments described above, and rather intended to include the following appended claims, and all modifications, equivalents, and alternatives falling within the spirit and scope of the following claims.

What is claimed is:

1. A battery diagnosis apparatus comprising:
a voltage deviation determining unit configured to determine a voltage deviation of a battery cell group including a plurality of battery cells ; and
a processor and a memory configured to diagnose abnormal voltage variation in the battery cell group based on a variation in voltage deviation of the battery cell group.

2. The battery diagnosis apparatus of claim 1, further comprising a stabilization determining unit configured to determine whether the battery cell group is in a battery stabilization state that satisfies one or more diagnostic allowable conditions during a charging or parked state of a vehicle.

3. The battery diagnosis apparatus of claim 2, wherein the one or more diagnostic allowable conditions comprise at least one of:
a state of charge (SOC) being equal to or greater than a target level; or
a battery temperature being equal to or greater than a target temperature.

4. The battery diagnosis apparatus of claim 2, wherein the one or more diagnostic allowable conditions comprise at least one of a rate of current variation during charging or discharging being less than a target rate of current variation.

5. The battery diagnosis apparatus of claim 2, wherein the one or more diagnostic allowable conditions comprise a current time point being a time point at which a target wait time has elapsed after an ignition device was switched to an OFF state (IG OFF).

6. The battery diagnosis apparatus of claim 2, wherein the one or more diagnostic allowable conditions comprise no sensing error occurring in a voltage sensor during voltage sensing for the battery cell group.

7. The battery diagnosis apparatus of claim 1, wherein:
the voltage deviation determining unit is configured to determine a voltage deviation of the battery cell group as a difference between a reference battery cell voltage and a smallest battery cell voltage in the battery cell group, and
the reference battery cell voltage comprises one of:
a largest battery cell voltage in the battery cell group;
an average value of individual battery cell voltages in the battery cell group; or
a median value of the individual battery cell voltages in the battery cell group.

8. The battery diagnosis apparatus of claim 2, wherein the voltage deviation determining unit is configured to determine a voltage deviation of the battery cell group when a target wait time has elapsed from a time point at which the battery cell group is determined to be in a battery stabilization state.

9. The battery diagnosis apparatus of claim 1, further comprising a battery diagnosis unit, comprising the processor and the memory configured to:
diagnose abnormal voltage variation in the battery cell group based on a variation in voltage deviation of the battery cell group corresponding to an abnormal variation in voltage deviation equal to or greater than a diagnostic threshold,
the abnormal variation in voltage deviation increases consecutively for a target number of times or more, and
the consecutively increasing abnormal variation in voltage deviation is cumulatively detected at least the target number of times during one discharge cycle (1 DC).

10. The battery diagnosis apparatus of claim 9, further comprising a battery diagnosis unit, comprising the processor and the memory configured to:
compare voltage deviations of the battery cell group at respective time points spaced by a target time interval with one another, and
when a variation in voltage deviation, which is defined as a difference between a voltage deviation at a current time point and a voltage deviation at an immediately preceding time point, is first detected to be equal to or greater than the diagnostic threshold, compare voltage deviations at respective time points following the current time point based on the voltage deviation at the immediately preceding time point.

11. The battery diagnosis apparatus of claim 7, further comprising a battery diagnosis unit, comprising the processor and the memory configured to:
the battery diagnosis unit is configured to compare voltage deviations of the battery cell group at respective time points with one another when no voltage instability factor that causes the reference battery cell voltage to fluctuate is detected, and
an increase in the magnitude of the reference battery cell voltage does not result in an increase in the voltage deviation.

12. A method for diagnosing abnormal voltage variation performed by a battery diagnosis apparatus, the method comprising:
using a computing device comprising a processor and a memory:
determining a voltage deviation of a battery cell group,
wherein the battery cell group comprises a plurality of battery cells; and
diagnosing abnormal voltage variation in the battery cell group based on a variation in voltage deviation of the battery cell group.

13. The method of claim 12, wherein the diagnosing the abnormal voltage variation comprises determining whether the battery cell group is in a battery stabilization state that satisfies one or more diagnostic allowable conditions during a charging or parked state of a vehicle.

14. The method of claim 13, wherein the determining whether the battery cell group is in the battery stabilization state comprises determining that the battery cell group is in the battery stabilization state when a rate of current variation during charging or discharging is less than a target rate of current variation, based on the diagnostic allowable conditions.

15. The method of claim 12, wherein:
the determining the voltage deviation comprises determining a voltage deviation of the battery cell group as a difference between a reference battery cell voltage and a smallest battery cell voltage in the battery cell group, and
the reference battery cell voltage comprises one of:
a largest battery cell voltage in the battery cell group;
an average value of individual battery cell voltages in the battery cell group; or
a median value of the individual battery cell voltages in the battery cell group.

16. The method of claim 12, wherein:
the diagnosing the abnormal voltage variation comprises diagnosing abnormal voltage variation in the battery cell group based on a variation in voltage deviation of the battery cell group corresponding to an abnormal variation in voltage deviation equal to or greater than a diagnostic threshold,
the abnormal variation in voltage deviation increases consecutively for a target number of times or more, and
the consecutively increasing abnormal variation in voltage deviation is cumulatively detected at least the target number of times during one discharge cycle (1 DC).

17. The method of claim 16, wherein the diagnosing the abnormal voltage variation comprises:
comparing voltage deviations of the battery cell group at respective time points spaced by a target time interval with one another; and
when a variation in voltage deviation, which is defined as a difference between a voltage deviation at a current time point and a voltage deviation at an immediately preceding time point, is first detected to be equal to or greater than the diagnostic threshold, comparing voltage deviations at respective time points following the current time point based on the voltage deviation at the immediately preceding time point.

18. A battery diagnosis apparatus comprising:
a computing device comprising a processor a memory, wherein the memory is configured to store instructions that, when executed by the processor, are configured to cause the processor to:
determine a voltage deviation of a battery cell group,
wherein the battery cell group comprises a plurality of battery cells; and
diagnose abnormal voltage variation in the battery cell group based on a variation in voltage deviation of the battery cell group.

19. The battery diagnosis apparatus of claim 18, wherein:
the computing device is configured to determine a voltage deviation of the battery cell group as a difference between a reference battery cell voltage and a smallest battery cell voltage in the battery cell group, and
the reference battery cell voltage comprises one of:
a largest battery cell voltage in the battery cell group;
an average value of individual battery cell voltages in the battery cell group; or
a median value of the individual battery cell voltages in the battery cell group.

20. The battery diagnosis apparatus of claim 18, wherein:
the computing device is configured to diagnose abnormal voltage variation in the battery cell group based on a variation in voltage deviation of the battery cell group corresponding to an abnormal variation in voltage deviation equal to or greater than a diagnostic threshold,
the abnormal variation in voltage deviation increases consecutively for a target number of times or more, and
the consecutively increasing abnormal variation in voltage deviation is cumulatively detected at least the target number of times during one discharge cycle (1 DC).
